(19) United States
(12) Patent Application Publication
(10) Pub. No.: US 2020/0164412 A1
(43) Pub. Date: May 28, 2020

(54) METHOD OF CLEANING SEMICONDUCTOR EQUIPMENT AND SEMICONDUCTOR EQUIPMENT MANAGEMENT SYSTEM

(71) Applicant: SAMSUNG ELECTRONICS CO., LTD., Suwon-si (KR)

(72) Inventors: Kyoung-Whan Oh, Hwaseong-si (KR); Yun-Sek Oh, Sejong-si (KR); Ho-Youl Lee, Yongin-si (KR); Su-Man Park, Seoul (KR); Won-Ki Park, Seoul (KR); Young-Il Jang, Yongin-si (KR)

(21) Appl. No.: 16/502,836

(22) Filed: Jul. 3, 2019

(30) Foreign Application Priority Data
Nov. 23, 2018 (KR) 10-2018-0146775

(51) Int. Cl. B08B 7/02; B08B 9/053; G01N 29/04; G01F 23/292; G06N 3/08; H01L 21/67

(52) U.S. Cl. CPC B08B 7/028; B08B 9/053; G01N 29/043; H01L 21/67253; G06N 3/08; H01L 21/67248; G01F 23/2928

(57) ABSTRACT

A method of cleaning semiconductor equipment includes monitoring a state of a fluid in a pipeline of the semiconductor equipment, constructing a database by using data collected through the monitoring, diagnosing a state of the pipeline based on the data collected through the monitoring and stored in the database, and cleaning the pipeline by using an ultrasound wave when the state of the pipeline is diagnosed as being abnormal. The pipeline is cleaned by using at least two ultrasound wave generators.

### CROSS-REFERENCE TO RELATED APPLICATIONS

This application claims priority under 35 U.S.C. § 119 to Korean Patent Application No. 10-2018-0146775, filed on Nov. 23, 2018 in the Korean Intellectual Property Office, the disclosure of which is incorporated by reference herein in its entirety.

### TECHNICAL FIELD

Exemplary embodiments of the inventive concept relate to a method of cleaning semiconductor equipment and a semiconductor equipment management system, and more particularly, to a method of cleaning semiconductor equipment and a semiconductor equipment management system for cleaning and managing semiconductor equipment by using ultrasound waves.

### DISCUSSION OF THE RELATED ART

Semiconductor equipment discharges foreign substances generated during a semiconductor process through a pipeline. When a pipeline is used for a certain period of time, chemical reactions such as, for example, oxidation or deposition occurs. As a result, foreign substances such as sludge may build up and become piled on the inner surface of the pipeline.

Such sludge and other foreign matter protrude from the inner surface of the pipeline, thereby reducing the internal diameter of the pipeline, and also weakens the flow of a fluid in the pipeline, ultimately causing clogging of the pipeline and backflow of the fluid. As a result, the quality of semiconductor devices manufactured using the semiconductor equipment may deteriorate, and the semiconductor equipment may stop operation. When this occurs, the pipeline may be replaced, or sludge and other foreign substances in the pipeline may be removed by using a wire brush or a wire tool. However, replacing the pipeline is disadvantageous in terms of time and cost, and using a wire brush or a wire tool to clean the pipeline exhibits low efficiency in regards to removing foreign substances and may damage the pipeline.

### SUMMARY

Exemplary embodiments of the inventive concept provide a method of cleaning semiconductor equipment, and a semiconductor equipment management system capable of stably and efficiently cleaning and managing a pipeline of semiconductor equipment.

According to an exemplary embodiment, a method of cleaning semiconductor equipment includes monitoring a state of a fluid in a pipeline of the semiconductor equipment, constructing a database by using data collected through the monitoring, diagnosing a state of the pipeline based on the data collected through the monitoring and stored in the database, and cleaning the pipeline by using an ultrasound wave when the state of the pipeline is diagnosed as being abnormal. The pipeline is cleaned by using at least two ultrasound wave generators.

According to an exemplary embodiment, a method of cleaning semiconductor equipment includes monitoring a state of a fluid in a pipeline of semiconductor equipment, constructing a database by using data collected through the monitoring, diagnosing a state of the pipeline based on the data collected through the monitoring and stored in the database, and cleaning the pipeline by using bubbles and an ultrasound wave when the state of the pipeline is diagnosed as being abnormal. The bubbles are microbubbles or nanobubbles.

According to an exemplary embodiment, a system for managing semiconductor equipment includes a monitoring device configured to monitor a state of a fluid in a pipeline of the semiconductor equipment, a data storage device configured to store a database constructed using data collected through the monitoring device, a diagnosis device configured to diagnose a state of the pipeline based on the data collected through the monitoring device and stored in the database, and a cleaning device configured to clean the pipeline when the state of the pipeline is diagnosed as being abnormal. The cleaning device utilizes bubbles and at least two ultrasound wave generators.

### BRIEF DESCRIPTION OF THE DRAWINGS

The above and other features of the inventive concept will become more apparent by describing in detail exemplary embodiments thereof with reference to the accompanying drawings, in which:

FIG. 1 is a schematic flowchart of a method of cleaning semiconductor equipment according to an exemplary embodiment.

FIG. 2 is a conceptual diagram of a light sensor used for monitoring the state of a fluid in the method of cleaning semiconductor equipment of FIG. 1.

FIGS. 3A to 3C are a conceptual view, a partially enlarged perspective view, and a partial cross-sectional view, respectively, of a cleaning device used for cleaning a pipeline in the method of cleaning semiconductor equipment of FIG. 1.

FIGS. 4, 5A, 5B, 6A and 6B are conceptual diagrams showing a principle for generating multi-frequency ultrasound waves for cleaning a pipeline in the method of cleaning semiconductor equipment of FIG. 1.

FIG. 7 is a schematic flowchart of a method of cleaning semiconductor equipment according to an exemplary embodiment.

FIGS. 8A and 8B are conceptual diagrams showing a method of adding nano-micro bubbles to a fluid for cleaning a pipeline in the method of cleaning semiconductor equipment of FIG. 7.

FIGS. 9A and 9B are photographs showing experimental results showing the effect of removing sludge by using ultrasound waves and nano-micro bubbles.

FIG. 10 is a schematic flowchart of a method of cleaning semiconductor equipment according to an exemplary embodiment.

FIG. 11 is a schematic block diagram of a semiconductor equipment management system according to an exemplary embodiment.

### DETAILED DESCRIPTION OF THE EXEMPLARY EMBODIMENTS

Exemplary embodiments of the inventive concept will be described more fully hereinafter with reference to the accompanying drawings. Like reference numerals may refer to like elements throughout the accompanying drawings.

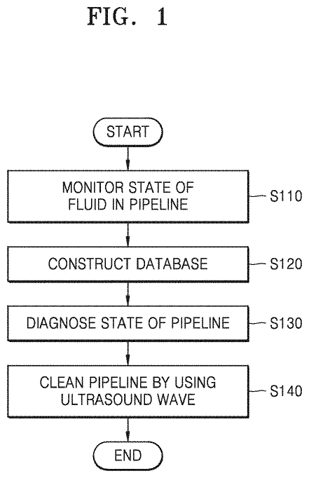

FIG. 1 is a schematic flowchart of a method of cleaning semiconductor equipment according to an exemplary embodiment.

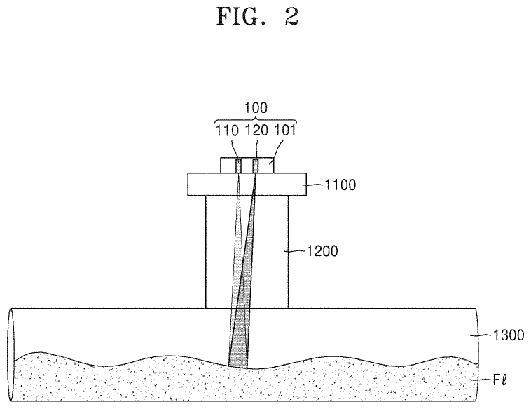

Referring to FIG. 1, in the method of cleaning semiconductor equipment according to an exemplary embodiment, the state of a fluid in a pipeline (see 1300 of FIG. 2) of semiconductor equipment is monitored first (operation S110). Herein, the semiconductor equipment may refer to all equipment that performs semiconductor processing. For example, the semiconductor equipment may include deposition equipment, lithography equipment, etching equipment, ashing equipment, cleaning equipment, ion implantation equipment, chemical-mechanical polishing (CMP) equipment, etc. However, it is to be understood that the semiconductor equipment is not limited thereto.

Herein, the fluid may refer to a fluidic gas and/or liquid including a foreign substance or a harmful gas generated during a semiconductor process. Such a fluid may be discharged to the outside through a pipeline 1300 of the semiconductor equipment. Characteristics of foreign substances or harmful gases included in a fluid may be changed due to chemical reactions while being discharged through the pipeline 1300 and may cause side effects such as, for example, contamination, pressure change, temperature/humidity change, and pipeline clogging.

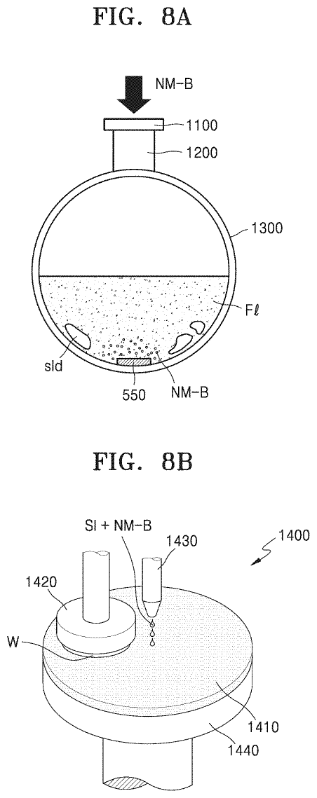

Semiconductor process equipment using a gas or a solvent, e.g., CMP equipment (see 1400 of FIG. 8B), will be described as an example. The CMP equipment 1400 is equipment that uses a combination of a physical method and a chemical method to polish a wafer by a desired thickness. In the CMP equipment 1400, a solution called slurry may be used to change the film properties of a wafer by using a chemical method. The slurry includes various chemical substances based on de-ionized water (DIW), and particularly, includes granular components for polishing. The property of the slurry is changed by a high temperature due to the friction between a wafer and a pad and a high pressure due to the pressure of a head spindle through a CMP process, and tends to be transformed into a sludge when discharged through the pipeline 1300 with other slurries and a cleaning fluid. Such a sludge is easily deposited and adhered to the inner wall of a pipeline due to reasons including, for example, a narrow pipeline, a low head (or a low slope) of a pipeline, and pipeline contamination. Once deposition starts, it becomes easier and more likely that deposition will subsequently continue. Therefore, the thickness of a sludge layer tends to rapidly increase due to progress of the deposition. When a pipeline is clogged due to the sludge, the drainage backflows and is detected by a leak sensor provided in the CMP equipment 1400, and the CMP equipment 1400 automatically stops operating to prevent product failure due to contamination.

To prevent the backflow of a fluid in the pipeline 1300, a fluid level is frequently monitored through visual inspection by using an observation window (see 1100 of FIG. 2) provided at the pipeline 1300. When the fluid level increases above a certain level, the pipeline 1300 may be cleaned by using a tool to prevent backflow of wastewater. However, when the fluid level increases sharply and the pipeline 1300 is not immediately cleaned, all equipment connected to the pipeline 1300 may stop. In this case, all wafers introduced in a process are discarded and all equipment does not resume operation until the problem of the pipeline 1300 is cleared. As a result, productivity may be significantly lowered.

In the method of cleaning semiconductor equipment according to an exemplary embodiment, the state of a fluid or the surrounding environment in the pipeline 1300 may be monitored by using various methods in operation S110. For example, the state of the pipeline 1300 may be monitored in real time by measuring a fluid level or a flow rate of a fluid in the pipeline 1300 by using an ultrasound wave sensor or a light sensor (see 100 of FIG. 2).

In the case of an ultrasound wave sensor, the fluid level of a fluid flowing in the pipeline 1300 may be measured by punching a hole through the observation window 1100 and mounting the ultrasound wave sensor thereto. Such an ultrasound wave sensor may accurately and efficiently obtain a result of linear displacement of a fluid through the time-of-flight (TOF) method by directly radiating an ultrasound wave to the fluid. However, since the ultrasound wave sensor is mounted in a hole punched through the observation window 1100, the ultrasound wave sensor may be directly exposed to the risk of overflow when the fluid in the pipeline 1300 is a hazardous material.

In contrast, a light sensor 100 may be mounted to the observation window 1100 without punching a hole through the observation window 1100. Thus, unlike the ultrasound wave sensor, the light sensor 100 is not directly exposed to the risk of overflow when the fluid in the pipeline 1300 is a hazardous material. Further, the light sensor 100 may be capable of more stably measuring the fluid level of a fluid in the pipeline 1300 by emitting light through the observation window 1100 to irradiate the fluid and receiving light reflected from the fluid. The light sensor 100 will be described below in more detail with reference to FIG. 2.

In exemplary embodiments, a laser sensor or a pulse sensor may be used as a sensor for measuring the fluid level of a fluid in the pipeline 1300.

The ultrasound wave sensor may measure the flow rate of a fluid in the pipeline 1300 based on time elapsed until an ultrasound wave is transmitted through the fluid and reflected, and may measure the number of particles in the fluid by measuring scattering of an ultrasound wave. In operation S110, when monitoring the state of a fluid, a fluid concentration or a gas concentration may be measured by using an ultrasound wave concentration sensor or a gas sensor for a gas such as, for example, NH₃. For example, a gas sensor may be used to measure the concentration for a gas such as, for example, NH₃ in the pipeline 1300. Furthermore, in operation S110, measurement of the temperature of the fluid using a temperature sensor, measurement of the pressure inside the pipeline 1300 or the pressure of a fluid using a pressure sensor, measurement of noise in the pipeline 1300 using an acoustic sensor, and measurement of vibration in the pipeline 1300 using a vibration sensor may be performed.

In the method of cleaning semiconductor equipment according to an exemplary embodiment, in operation S110, various sensors described above may be utilized to monitor the state of a fluid or the surrounding environment in the pipeline 1300. As a result, more diverse and objective data regarding the state of the fluid or the surrounding environment of the pipeline 1300 may be obtained. Also, by monitoring the state of a fluid in the pipeline 1300 in real time through various sensors, the manpower needed for visual inspection may be reduced and subjective judgment by a person may be excluded.

Next, a database is constructed by using actual measurement data obtained through the monitoring operation (operation S120). Such a database may be used as a basis for determining and diagnosing the state of the pipeline 1300. For example, the state of the pipeline 1300 may be determined and diagnosed based on data collected and stored in the database.

Thereafter, the state of the pipeline 1300 is diagnosed based on the data stored in the database (operation S130). The diagnosis of the state of the pipeline 1300 may be performed through various methods. For example, the state and the surrounding environment of the pipeline 1300 may be analyzed and diagnosed based on a database constructed by using actual measurement data, which is a collection of data obtained by monitoring the state of a fluid or the surrounding environment in the pipeline 1300, and the actual measurement data on such a database. For example, the actual measurement data may be used to check the fluid level and the flow rate of a fluid, particles and sludge in the fluid, and the concentration and the pressure of the fluid in real time. Based on the data regarding the state of the fluid, the state and the surrounding environment inside the pipeline 1300 may be diagnosed. For example, based on averages of actual measurement data and data at the times of previous accidents, respective reference values for the states of a fluid are set, and the state and the surrounding environment of the pipeline 1300 may be analyzed and diagnosed by comparing the actual measurement data to corresponding reference values.

For example, in an exemplary embodiment, a number of measurements may be performed on the pipeline 1300. The results of these multiple measurements may be stored and used to generate reference values. These reference values allow for a determination to be made in regards to when the state of the pipeline 1300 is abnormal.

As an example, when the actual measurement data from the current measurement of the pipeline 1300 is an outlier compared to reference values corresponding to the pipeline 1300 operating in a normal state, it may indicate that the pipeline 1300 is in an abnormal state. As another example, when the actual measurement data from the current measurement of the pipeline 1300 is similar to reference values corresponding to a pipeline 1300 operating in an abnormal state (e.g., reference values corresponding to previous accidents), it may indicate that the pipeline 1300 is currently in an abnormal state. When the pipeline 1300 is diagnosed as being in an abnormal state, a cleaning process may be performed on the pipeline 1300, as described in further detail below.

In an exemplary embodiment, the reference values may be set based on previous measurements of the pipeline 1300 and/or previous measurements of other pipelines.

In an exemplary embodiment, statistical diagnostic indices such as, for example, an hourly average fluid level, a daily average fluid level, a daily maximum fluid level, and a daily fluid level change may be calculated based on the data stored in the database, and the state and the surrounding environment of the pipeline 1300 may be diagnosed based on the statistical diagnostic indices. For example, when the flow rate is gradually slowed and a swell occurs due to a significant fluid level change, it may be a sign that the pipeline 1300 is starting to get clogged due to sludge. Therefore, the state and the surrounding environment of the pipeline 1300 may be predicted and detected through the statistical diagnostic indices.

In an exemplary embodiment, the diagnosis of the state of the pipeline 1300 may be performed based on deep learning using a database. Deep learning is a type of neural network model of machine learning, which relates to artificial intelligence. For example, machine learning is a technology that realizes a function similar to a human learning ability on a computer, and deep learning is a sub-concept of machine learning. Various learning algorithms may be used for deep learning. For example, artificial neural network (ANN), deep neural network (DNN), convolution neural network (CNN), recurrent neural network (RNN), and generative adversarial networks (GAN) may be used for deep learning. However, the learning algorithms that may be used for deep learning are not limited thereto.

In an exemplary embodiment, the diagnosis of the state of the pipeline 1300 may be independently performed based on actual measurement data from each sensor, or may be performed altogether by integrating actual measurement data from all sensors.

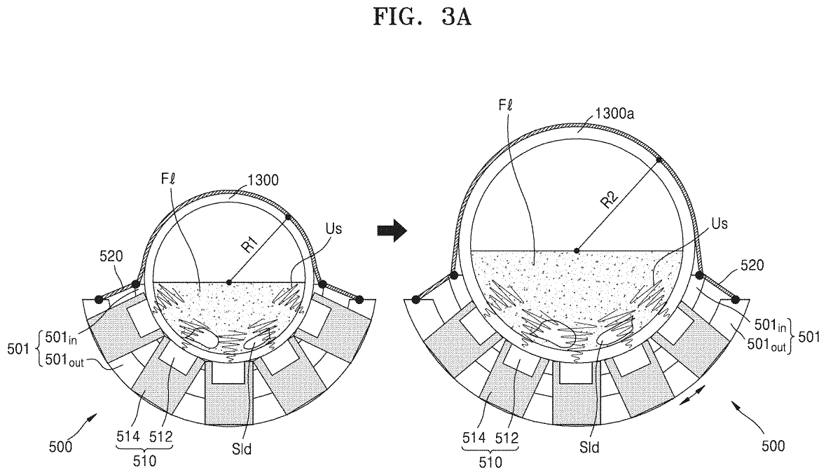

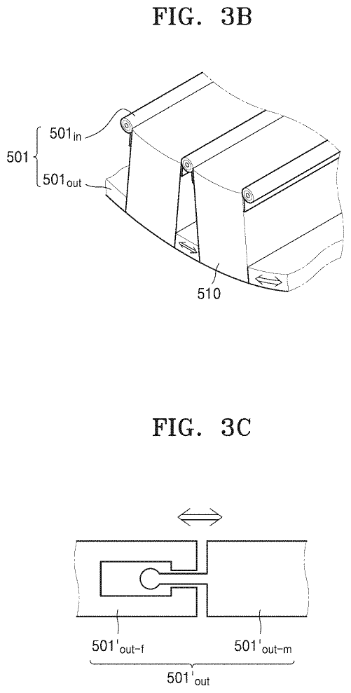

Thereafter, the pipeline 1300 is cleaned by using an ultrasound wave according to a result of the diagnosis of the pipeline 1300 (operation S140). For example, when it is determined in operation S130 that the state of the pipeline 1300 is poor and the pipeline 1300 should be cleaned (e.g., when the pipeline 1300 is diagnosed as being in an abnormal state in operation S130), an ultrasound wave may be irradiated onto a fluid in the pipeline 1300 to clean the pipeline 1300 by dissolving sludge adhered to and piled in the pipeline 1300. An ultrasound wave may be generated through an ultrasound wave generator (see 510 of FIG. 3A) disposed in contact with the outer wall of the pipeline 1300. Sludge adhered to the inner wall of the pipeline 1300 may be efficiently removed by generating an ultrasound wave of a frequency appropriate for dissolving the sludge through an ultrasound wave generator 510, and irradiating the fluid with the ultrasound wave in the pipeline 1300. The cleaning of the pipeline 1300 using an ultrasound wave will be described below in more detail with reference to FIGS. 3A to 3C.

In the method of cleaning semiconductor equipment according to an exemplary embodiment, the state of a fluid in the pipeline 1300 is monitored in real time by using various sensors, a database is constructed by using data obtained from the monitoring, and the state of the pipeline 1300 is diagnosed by using, for example, deep learning or the like. Therefore, the state of the pipeline 1300 may be objectively and accurately diagnosed. For example, problems that may arise from subjective and inaccurate determinations through a visual inspection performed by a human may be eliminated or reduced. Also, in the method of cleaning semiconductor equipment according to an exemplary embodiment, the pipeline 1300 may be cleaned in a stable and efficient manner by cleaning the pipeline 1300 using an ultrasound wave of an appropriate frequency. For example, damage of the pipeline 1300 or deterioration of cleaning efficiency that may occur in a method of cleaning the pipeline 1300 by inserting a wire brush or a wire tool into the pipeline 1300 through an observation window may be avoided. Also, unlike a cleaning operation performed using a wire brush or a wire tool, the pipeline 1300 may be cleaned without stopping all equipment connected to the pipeline 1300, thus, improving efficiency.

FIG. 2 is a conceptual diagram of a light sensor used for monitoring the state of a fluid in the method of cleaning semiconductor equipment of FIG. 1. For convenience of explanation, a further description of elements and technical aspects previously described may be omitted.

Referring to FIG. 2, the light sensor 100 may be attached to the observation window 1100 installed on the pipeline 1300. As shown in FIG. 2, the observation window 1100 may be installed on the pipeline 1300 via a connection pipe 1200.

The light sensor 100 may be attached onto the observation window 1100 by using a fixing bracket. For example, the light sensor 100 may be attached onto the observation window 1100 with various types of optical cables and various types of fixing brackets. In the case of a straight optical cable, light loss is small and light may be efficiently emitted and received therethrough. In the case of a bent optical cable, there may be some physical light loss, but the bent optical cable may be easily installed in a narrow space in which the pipeline 1300 is located. Also, various types of fixing brackets may be designed, manufactured, and used depending on the shape of each optical cable and the shape of the observation window 1100.

The light sensor 100 may include a light emitter 110 for emitting light, a light receiver 120 for receiving light, and a body 101 for accommodating and supporting the light emitter 110 and the light receiver 120. The light emitter 110 may include, for example, an LED light source. However, the light source included in the light emitter 110 is not limited thereto. The light sensor 100 emits light from the light emitter 110 to irradiate a fluid Fl in the pipeline 1300 with light in a vertical direction, receives light reflected according to the fluid level of the fluid Fl through the light receiver 120, and measures the intensity of the reflected light, thereby calculating the fluid level of the fluid Fl. The light sensor 100 is generally used as a detection sensor for determining whether an object exists at a particular position, but may also be used as a displacement sensor for measuring a distance by detecting and converting the nonlinearity of light intensity.

The light sensor 100 may be attached to the observation window 1100 without punching a hole through the observation window 1100, and thus, the light sensor 100 may be safe from the risk due to the overflow of the fluid Fl. For example, in the case of the CMP equipment 1400 described above, since a fluid may include harmful substances, the light sensor 100 may be highly useful for safely measuring the fluid level without punching a hole through the observation window 1100.

The intensity of light collected by the light sensor 100 may vary depending on a distance between the light sensor 100 and the surface of the fluid Fl. However, when light is emitted and received through the observation window 1100, loss of light due to a diffused reflection caused by bubbles on the surface of the fluid Fl and absorption of light by the black surface of the fluid Fl may increase. As a result, measurement of the intensity of light per distance may be highly inaccurate. For example, the measured intensity of light per distance may be significantly smaller than the actual light per distance. To account for this, a high-power light source employing a high-brightness LED may be used. However, in the case of using a high-power light source, when the distance between the light sensor 100 and the surface of the fluid Fl is small, light saturation may easily occur, and thus, it may be difficult to accurately measure a displacement within the range where light saturation is occurring. To account for this, a distance between the light emitter 110 and the light receiver 120 in the light sensor 100 may be adjusted/optimized. Accordingly, by optimizing the distance between the light emitter 110 and the light receiver 120, light saturation may be avoided while using a high-power light source, and thus, displacement may be precisely measured over the entire range.

FIGS. 3A to 3C are a conceptual view, a partially enlarged perspective view, and a partial cross-sectional view, respectively, of a cleaning device used for cleaning a pipeline in the method of cleaning semiconductor equipment of FIG. 1. For convenience of explanation, a further description of elements and technical aspects previously described may be omitted.

Referring to FIGS. 3A to 3C, a cleaning device 500 may include a flexible structure 501, an ultrasound wave generator 510, and a coupling mechanism 520.

The ultrasound wave generator 510 may include a core 512 and a housing 514. The core 512 may generate an ultrasound wave Us of a certain frequency. The housing 514 may accommodate and support the core 512. Various circuits and components connected to the core 512 may be arranged inside the housing 514. A plurality of ultrasound wave generators 510 may be attached to the pipeline 1300 via the flexible structure 501. Although FIG. 3A illustrates five ultrasound wave generators 510 attached to the pipeline 1300, it is to be understood that the number of ultrasound wave generators 510 is not limited thereto. For example, in exemplary embodiments, one to four or six or more ultrasound wave generators 510 may be attached to the pipeline 1300.

The flexible structure 501 may include an inner portion 501ᵢₙ and an outer portion 501ₒᵤₜ. The outer portion 501ₒᵤₜ may include a rubber-like elastic material. The outer portion 501ₒᵤₜ may be a component having elasticity such as, for example, a spring. Further, as shown in FIG. 3C, an outer portion 501′ₒᵤₜ may have a coupling structure of which the length may be changed. For example, the outer portion 501′ₒᵤₜ may have a structure in which a female portion 501′_{out-f} and a male portion 501′ₒᵤₜ₋ₘ are combined with each other. The male portion 501′ₒᵤₜ₋ₘ may include a protruding member that is disposed within a recess of the female portion 501′_{out-f}. The protruding member of the male portion 501′ₒᵤₜ₋ₘ may move within the recess of the female portion 501′_{out-f} in the horizontal direction indicated in FIG. 3C. As a result, the length of the outer portion 501′ₒᵤₜ may be adjusted. Thus, in exemplary embodiments, the outer portion 501ₒᵤₜ or 501′ₒᵤₜ may include a material or a mechanism of which the length may be freely adjusted.

The inner portion 501ᵢₙ may also include a material having elasticity or a mechanism of which the length may be adjusted. Also, the inner portion 501ᵢₙ may include a mechanism such as, for example, a hinge as shown in FIG. 3B. In the flexible structure 501 of FIG. 3A, the inner portion 501ᵢₙ and the outer portion 501ₒᵤₜ are separated from each other. However, according to exemplary embodiments, the flexible structure 501 may be a single structure without a distinction between the inner portion 501ᵢₙ and the outer portion 501ₒᵤₜ.

The coupling mechanism 520 may couple and fix the flexible structure 501 to the pipeline 1300. The coupling mechanism 520 is connected to the inner portion 501ᵢₙ and the outer portion 501ₒᵤₜ of the flexible structure 501 and, as shown in FIG. 3A, has a structure that surrounds the outer wall of the pipeline 1300, thereby coupling the flexible structure 501 to the pipeline 1300. The coupling mechanism 520 may include a coupling unit such as, for example, a belt buckle, and may detachably attach the flexible structure 501 to the pipeline 1300.

In an exemplary embodiment, the coupling mechanism 520 may partially surround a portion of the outer wall of the pipeline 1300, and the flexible structure 501 may partially surround another portion of the outer wall of the pipeline 1300. For example, in an exemplary embodiment, neither the coupling mechanism 520 nor the flexible structure 501 entirely surrounds the outer wall of the pipeline 1300, but rather, each of the coupling mechanism 520 and the flexible structure 501 partially surrounds different portions of the outer wall of the pipeline 1300. For example, as shown in FIG. 3A, in an exemplary embodiment, the coupling mechanism 520 may surround an upper portion of the outer wall of the pipeline 1300, and the flexible structure 501 may surround a lower portion of the outer wall of the pipeline 1300.

The length of the coupling mechanism 520 may be adjusted through the coupling unit. Therefore, in an exemplary embodiment, the coupling mechanism 520 does not include an elastic material and is not a mechanism having elasticity. However, according to exemplary embodiments, the coupling mechanism 520 may also include an elastic material or may be a mechanism having elasticity.

The ultrasound wave generators 510 may be coupled to the flexible structure 501, thus being installed on the pipeline 1300. Also, due to the flexible characteristic of the flexible structure 501, the ultrasound wave generators 510 may be arranged to freely contact the outer wall of the pipeline 1300, regardless of the size of the pipeline 1300. For example, referring to FIG. 3A, even when a left pipeline 1300 has an inner radius corresponding to a first radius R1 and a right pipeline 1300a has an inner radius corresponding to a second radius R2 greater than the first radius R1, the same cleaning device 500 may be freely placed at either the left pipeline 1300 or the right pipeline 1300a due to the flexible structure 501. Accordingly, the ultrasound wave generators 510 of the cleaning device 500 may be freely attached to the outer wall of either the left pipeline 1300 or the right pipeline 1300a.

The ultrasound wave generators 510 may be arranged to surround the lower portion of the outer wall of the pipeline 1300. Generally, the fluid Fl is located at the lower portion of the pipeline 1300, and thus, most of the sludge Sld may also be formed and adhered to the lower portion of the inner wall of the pipeline 1300. Therefore, the ultrasound wave generators 510 may be arranged at the lower portion of the outer wall of the pipeline 1300 to surround the lower portion of the outer wall of the pipeline 1300 to improve the effect of removing the sludge Sld.

The ultrasound wave Us may provide various sludge removal effects depending on power and wavelength. For example, the effect of removing the sludge Sld may be improved by using higher frequencies for smaller particles of the sludge Sld and using lower frequencies for larger particles of the sludge Sld. For example, in the case of using a high power ultrasound wave having a high frequency, the effect of cleaning the pipeline 1300 may be improved due to the cavitation. The cavitation may refer to a phenomenon in which ultrafine bubbles corresponding to the wavelength of an ultrasound wave are formed and burst.

By choosing the frequency and power of the ultrasound wave Us to use according to the material of the pipeline 1300, the diameter of the pipeline 1300, and a pipeline connection method, an effective cleaning method with less side effects such as, for example, cracks and leaks of the pipeline 1300, may be implemented. Also, to improve the cleaning effect, the positions at which to install the ultrasound wave generators 510 may be selected in consideration of the characteristics that clogging of the pipeline 1300 due to the sludge Sld may be more likely at a curved pipe portion at which an angle of the pipeline 1300 is changed and a portion at which the flow rate is slow due to a low head and the characteristics that the sludge Sld is piled from the lower portion of the pipeline 1300 due to the weight of the sludge Sld.

In the method of cleaning semiconductor equipment according to an exemplary embodiment, the ultrasound wave generator 510 may be removable. For example, the ultrasound wave generator 510 may be attached to and detached from the pipeline 1300 by using the flexible structure 501 and the coupling mechanism 520, regardless of the size and the position of the pipeline 1300. As a result, the pipeline 1300 may be effectively cleaned with a small number of ultrasound wave generators 510. Also, in the method of cleaning semiconductor equipment according to an exemplary embodiment, since the ultrasound wave generator 510 is installed on the outer wall of the pipeline 1300, the pipeline 1300 may be safely cleaned without stopping equipment connected to the pipeline 1300 or risking exposure to harmful substances by having an opening in the observation window 1100.

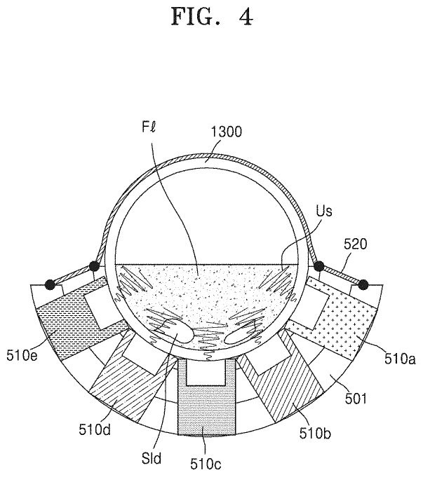

FIGS. 4, 5A, 5B, 6A and 6B are conceptual diagrams showing a principle for generating multi-frequency ultrasound waves for cleaning a pipeline in the method of cleaning semiconductor equipment of FIG. 1. For convenience of explanation, a further description of elements and technical aspects previously described may be omitted.

Referring to FIG. 4, five ultrasound wave generators 510a, 510b, 510c, 510d and 510e may be attached to the pipeline 1300 through the flexible structure 501 and the coupling mechanism 520. The ultrasound wave generators 510a, 510b, 510c, 510d and 510e may generate ultrasound waves of the same frequency. For example, the ultrasound wave generators 510a, 510b, 510c, 510d and 510e may generate ultrasound waves of about 40 kHz. However, the frequency of the ultrasound waves generated by the ultrasound wave generators 510a, 510b, 510c, 510d, and 510e is not limited to about 40 kHz.

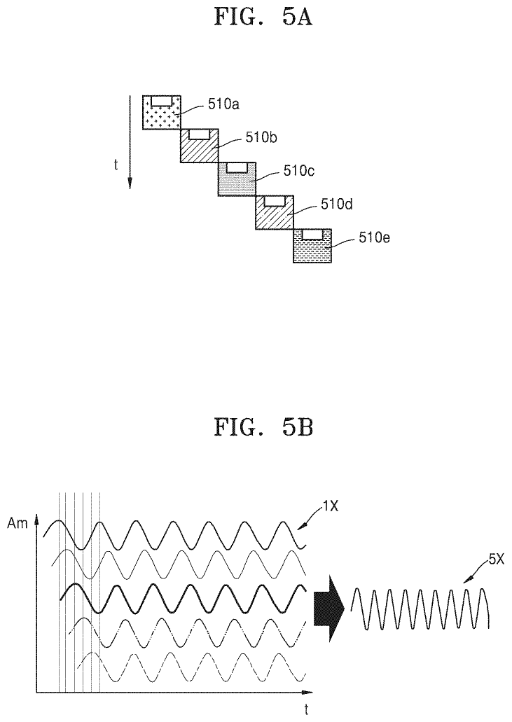

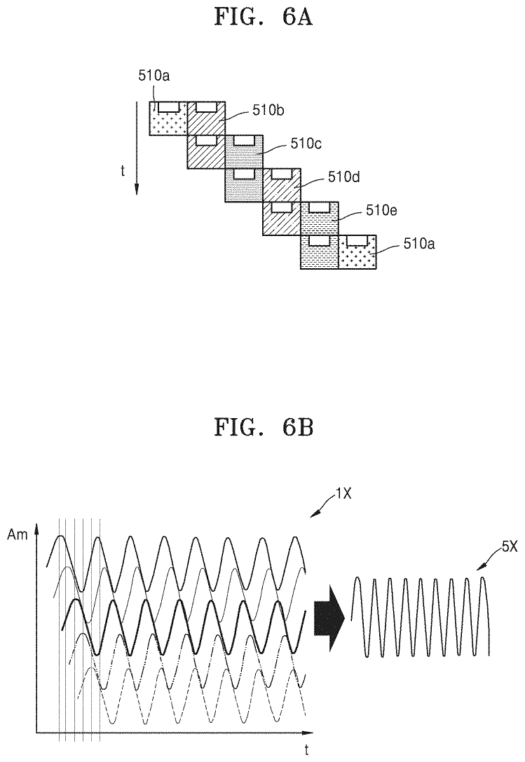

When ultrasound wave generators generating ultrasound waves of the frequency of 1× generate ultrasound waves at the same ultrasound wave generation time point, only ultrasound waves of the frequency of 1× may be generated. However, as described below with reference to FIGS. 5A, 5B, 6A and 6B, multi-frequency ultrasound waves may be generated when the ultrasound wave generation time points are diversified.

Referring to FIGS. 5A and 5B, it is assumed that the ultrasound wave generators 510a, 510b, 510c, 510d and 510e sequentially generate ultrasound waves having the frequency of 1×, as indicated by a downward arrow in FIG. 5A. A first ultrasound wave generator 510a at the top position may correspond to a first ultrasound wave generator 510a at the rightmost position in FIG. 4, and second to fifth ultrasound wave generators 510b, 510c, 510d and 510e sequentially arranged in the downward direction may correspond to second to fifth ultrasound wave generators 510b, 510c, 510d and 510e arranged in the clockwise direction in FIG. 4, respectively.

As described above, when the ultrasound wave generators 510a, 510b, 510c, 510d and 510e generate ultrasound waves at different time points instead of generating ultrasound waves at the same time point, as shown in FIG. 5B, although each of the ultrasound waves has the frequency of 1×, a synthesized ultrasound wave may have the frequency of up to 5×. For example, when the frequency of 1× is about 40 kHz, an ultrasound wave of the frequency up to about 200 kHz may be generated by using five ultrasound wave generators.

In FIG. 5B, the x-axis represents time and the y-axis represents the amplitude of an ultrasound wave. Also, the waveforms from above may respectively correspond to ultrasound waves generated by the ultrasound wave generators 510a, 510b, 510c, 510d and 510e from above in FIG. 5A, and the waveform on the right may correspond to a synthesized ultrasound wave.

Referring to FIGS. 6A and 6B, it is assumed that pairs of the ultrasound wave generators 510a, 510b, 510c, 510d and 510e sequentially generate ultrasound waves of the frequency of 1×, as indicated by a downward arrow in FIG. 6A. The ultrasound wave generators 510a, 510b, 510c, 510d and 510e may also correspond to the ultrasound wave generators 510a, 510b, 510c, 510d and 510e in FIG. 4.

As described above, when the ultrasound wave generators 510a, 510b, 510c, 510d and 510e generate ultrasound waves at different time points instead of generating ultrasound waves at the same time point, as shown in FIG. 6B, although each of the ultrasound waves has the frequency of 1×, a synthesized ultrasound wave may have the frequency of up to 5×. Also, since a pair of ultrasound wave generators generates ultrasound waves at the same generation time point each time, the amplitude of the pair of ultrasound wave generators is twice as large as the amplitude of an ultrasound wave generated by one ultrasound wave generator, and the amplitude of a synthesized ultrasound wave may be twice as large as the amplitude of the synthesized ultrasound wave of FIG. 5B. In FIG. 6B, the x-axis represents time and the y-axis represents the amplitude of an ultrasound wave. Also, the waveforms from above may respectively correspond to ultrasound waves generated by pairs of the ultrasound wave generators 510a and 510b, 510b and 510c, 510c and 510d, 510d and 510e, and 510e and 510a from above in FIG. 6A, and the waveform on the right may correspond to a synthesized ultrasound wave.

A method of generating multi-frequency ultrasound waves has been described with reference to an exemplary embodiment in which the ultrasound wave generators 510a, 510b, 510c, 510d and 510e generate ultrasound waves at different generation time points, and an exemplary embodiment in which pairs of the ultrasound wave generators 510a and 510b, 510b and 510c, 510c and 510d, 510d and 510e, and 510e and 510a generate ultrasound waves at different generation time points. However, the methods of generating multi-frequency ultrasound waves according to exemplary embodiments are not limited thereto. For example, ultrasound waves having the frequency of 2×, 3×, 4×, etc. may be generated by changing generation time points of the ultrasound waves. Also, by generating ultrasound waves by pairs of three or more at different generation time points, the amplitudes of the ultrasound waves may be variously changed. In the above-described exemplary embodiments, the ultrasound wave generators 510a, 510b, 510c, 510d and 510e continuously generate ultrasound waves after initially generating ultrasound waves. However, exemplary embodiments are not limited thereto. For example, in an exemplary embodiment, ultrasound waves may be intermittently generated by turning each of the ultrasound wave generators 510a 510b, 510c, 510d and 510e ON and OFF, thereby further diversifying multi-frequency ultrasound waves.

The optimal frequency of an ultrasound wave for removing the sludge may vary depending on the temperature of a fluid. Therefore, based on temperature information provided by a user or temperature information obtained through a temperature sensor, the frequency of an ultrasound wave may be adjusted/corrected to a frequency that will effectively remove the sludge.

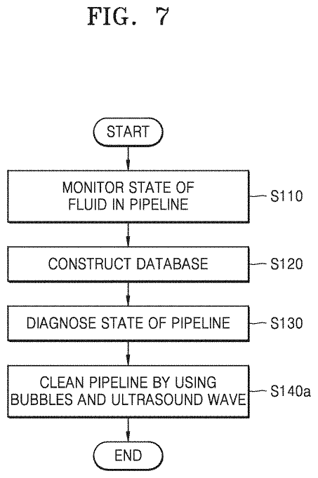

FIG. 7 is a schematic flowchart of a method of cleaning semiconductor equipment according to an exemplary embodiment. For convenience of explanation, a further description of elements and technical aspects previously described may be omitted.

Referring to FIG. 7, a method of cleaning semiconductor equipment according to an exemplary embodiment may be different from the method of cleaning semiconductor equipment according to the exemplary embodiment of FIG. 1 in that bubbles and ultrasound waves are used together in operation S140a for cleaning a pipeline. In the method of cleaning semiconductor equipment according to the exemplary embodiment of FIG. 7, operation S110 for monitoring the state of a fluid, operation S120 for constructing a database, and operation S130 for diagnosing the state of a pipeline are identical to those described above with reference to FIG. 1.

However, in the method of cleaning semiconductor equipment according to the exemplary embodiment of FIG. 7, in operation S140a for cleaning a pipeline (see 1300 in FIG. 2), the pipeline 1300 may be cleaned by using bubbles as well as ultrasound waves.

The bubbles may be, for example, microbubbles or nanobubbles. Microbubbles generally have bubble sizes of up to about 50 μm, may rise at the rate of about 3 mm per minute and stay in a fluid for a long time due to a low buoyancy, and may be completely dissolved when contracted and disappear. Nanobubbles are ultrafine air bubbles that have sizes up to about 5 jam and may not be seen by the naked eye, have sizes up to about 1/2000 of normal bubbles, and are finer than about 25 μm, which is about equal to the size of pores of the skin. Nanobubbles may be generated as microbubbles in a fluid are reduced to nanosizes or by a separate bubble generator. Microbubbles slowly rise and may stay in a fluid for more than dozens of minutes, and nanobubbles may stay in the fluid longer. For example, nanobubbles may stay in a fluid for several hours. Microbubbles may be generated through, for example, pressurized melting, rotary shearing, and pressurized rotary shearing. Hereinafter, nanobubbles and microbubbles will be collectively referred to as nano-micro bubbles without any distinction.

As described above, nano-micro bubbles rise very slowly toward the surface of a fluid, and most of the nano-micro bubbles disappear at the surface of the fluid. Various types of energy including an ultrasound wave of about 40 kHz, high sound pressure of about 140 dB, and instantaneous heat from about 4000° C. to about 6000° C. may be generated. Such energy may be used as an effective energy source for dissolving the sludge. Also, nano-micro bubbles may generate free radicals with an oxidation potential of about 2000 times that of ozone. Free radicals have an excellent disinfecting ability and are excellent at decomposing non-degradable chemical substances, and thus, are often used in water quality improvement and purification technology in various industrial fields.

By adding the nano-micro bubbles to a fluid and applying an ultrasound wave thereto, the effect of cleaning the pipeline 1300 may be further improved. Nano-micro bubbles may be directly added to a fluid in a pipeline or may be added during a semiconductor process (e.g., during a semiconductor manufacturing/fabrication process) based on the characteristic that nano-micro bubbles stay in a fluid for a long time. The addition of nano-micro bubbles to a fluid will be described below in more detail with reference to FIGS. 8A and 8B.

According to exemplary embodiments, the pipeline 1300 may be cleaned by using ultrasound waves only as described above with reference to the exemplary embodiment of FIG. 1, or by using nano-micro bubbles only.

FIGS. 8A and 8B are conceptual diagrams showing a method of adding nano-micro bubbles to a fluid for cleaning a pipeline in the method of cleaning semiconductor equipment of FIG. 7. FIG. 8A is a cross-sectional view of a pipeline. FIG. 8B is a perspective view of CMP equipment. For convenience of explanation, a further description of elements and technical aspects previously described may be omitted.

Referring to FIG. 8A, nano-micro bubbles NM-B may be added directly into the fluid Fl in the pipeline 1300. For example, the nano-micro bubbles NM-B may be added to the fluid Fl by adding a liquid including the nano-micro bubbles NM-B at the starting point of the pipeline 1300 or at a midpoint of the pipeline 1300 through the observation window 1100. Also, according to exemplary embodiments, the nano-micro bubbles NM-B may be added to the fluid Fl by disposing a bubble generator 550 in the fluid Fl in the pipeline 1300 through the observation window 1100 and generating the nano-micro bubbles NM-B through the bubble generator 550.

In FIG. 8A, a plurality of ultrasound wave generators 510 may be attached to the outer wall of the pipeline 1300 through the flexible structure 501 and the coupling mechanism 520, as shown in FIG. 3A. Therefore, the pipeline 1300 may be effectively cleaned by using the ultrasound wave Us from the ultrasound wave generators 510 and the nano-micro bubbles NM-B.

Referring to FIG. 8B, the nano-micro bubbles NM-B may be added during a semiconductor process of semiconductor equipment. For example, since the CMP equipment 1400 is equipment for polishing and cleaning a wafer W, the nano-micro bubbles NM-B may be added. For example, when a CMP process is performed by adding the nano-micro bubbles NM-B to the slurry Sl or DIW used in a process for polishing the wafer W, the effect of cleaning particles generated during a polishing operation may be improved, and thus, the effect of cleaning the wafer W may be about doubled. Also, since remaining nano-micro bubbles NM-B help cleaning of sludge Sld in the pipeline 1300 using an ultrasound wave, the nano-micro bubbles NM-B may contribute to both wafer cleaning and pipeline cleaning.

As shown in FIG. 8B, in an exemplary embodiment, the CMP equipment 1400 may include a polishing pad 1410, a polishing head 1420, a dispenser 1430, and a polishing turntable 1440. The wafer W to be polished may be disposed between the polishing head 1420 and the polishing pad 1410 as shown in FIG. 8B, and the slurry Sl or DIW including the nano-micro bubbles NM-B may be supplied onto the polishing pad 1410 via the dispenser 1430.

In an exemplary embodiment, the nano-micro bubbles NM-B may be added either during a semiconductor process of semiconductor equipment or directly to a fluid in the pipeline 1300. In an exemplary embodiment, the nano-micro bubbles NM-B may be added both during a semiconductor process of semiconductor equipment and directly to a fluid in the pipeline 1300.

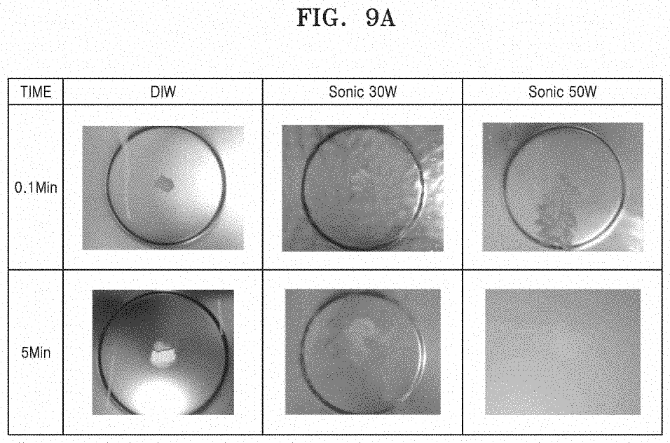

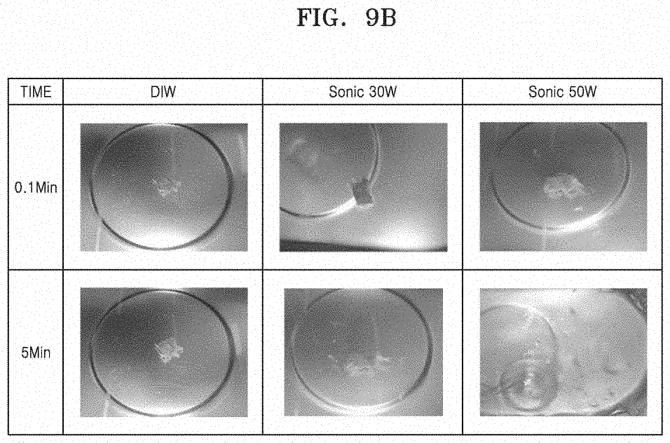

A CMP process may be divided into an oxide CMP process for removing only an oxide film, and a Cu CMP process for removing an oxide and copper (Cu) together. Also, ceria sludge may be generated during an oxide CMP process and Cu sludge may be generated during a Cu CMP process. This may occur because different chemical slurries are used in the respective processes. Generally, slurry may include hazardous substances such as, for example, sulfuric acid or hydrofluoric acid. The ceria sludge or the Cu sludge may be effectively and rapidly removed by using ultrasound waves and bubbles, and the effect will be described below based on experimental results with reference to FIGS. 9A and 9B.

FIGS. 9A and 9B are photographs showing experimental results showing the effect of removing sludge by using ultrasound waves and nano-micro bubbles.

Referring to FIG. 9A, the two photographs on the left are photographs respectively showing that Cu sludge in DIW was dissolved within 0.1 minutes and 5 minutes, the two photographs at the center are photographs respectively showing that ceria sludge in DIW was dissolved within 0.1 minutes and 5 minutes with a weak ultrasound wave of about 30 W, and the two photographs on the right are photographs respectively showing that ceria sludge in DIW was dissolved within 0.1 minutes and 5 minutes with a weak ultrasound wave of about 50 W. Here, the frequency of ultrasound waves used was about 40 kHz.

FIG. 9A shows that the ceria sludge was effectively dissolved with an ultrasonic wave of about 50 W and about 40 kHz within 5 minutes.

Referring to FIG. 9B, the two photographs on the left are photographs respectively showing that Cu sludge in DIW including nano-micro bubbles was dissolved within 0.1 minutes and 5 minutes, the two photographs at the center are photographs respectively showing that Cu sludge in DIW including nano-micro bubbles was dissolved within 0.1 minutes and 5 minutes with a weak ultrasound wave of about 30 W, and the two photographs on the right are photographs respectively showing that Cu sludge in DIW including nano-micro bubbles was dissolved within 0.1 minutes and 5 minutes with a weak ultrasound wave of about 50 W. Here, the frequency of ultrasound waves used was also 40 kHz.

FIG. 9B shows that the Cu sludge was effectively dissolved in DIW including nano-micro bubbles with an ultrasonic wave of about 50 W and about 40 kHz within 5 minutes. Accordingly, when nano-micro bubbles are used together with ultrasound waves, Cu sludge, which is less dissoluble, may be effectively dissolved.

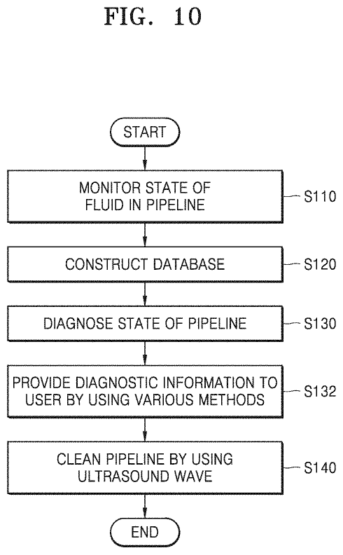

FIG. 10 is a schematic flowchart of a method of cleaning semiconductor equipment according to an exemplary embodiment. For convenience of explanation, a further description of elements and technical aspects previously described may be omitted.

Referring to FIG. 10, a method of cleaning semiconductor equipment according to an exemplary embodiment may be different from the method of cleaning semiconductor equipment according to the exemplary embodiment of FIG. 1 in that the method of cleaning semiconductor equipment according to the exemplary embodiment of FIG. 10 further includes operation S132 for providing diagnostic information to a user through various methods. For example, in the method of cleaning semiconductor equipment according to the exemplary embodiment of FIG. 10, operation S110 for monitoring the state of a fluid, operation S120 for constructing a database, and operation S130 for diagnosing the state of a pipeline are identical to those described above with reference to FIG. 1.

Thereafter, diagnostic information obtained in operation S130 for diagnosing the state of a pipeline is provided to a user through various methods (operation S132). For example, the diagnostic information may be provided to the user in real time in the form of at least one of, for example, sound, light, an e-mail, a text message, and an equipment interlock. Here, the sound may refer to a buzzer or the like which generates a warning sound, and the light may refer to a warning lamp or a lamp which is turned on or flickers.

Accordingly, by providing diagnostic information to a user in real time through various methods, the user may recognize the state of a pipeline in real time and take an appropriate action such as cleaning, thereby efficiently managing the pipeline and semiconductor equipment including the pipeline. In an exemplary embodiment, diagnostic information may be provided to a user only when it is determined in operation S130 that the state of the pipeline is poor. In an exemplary embodiment, diagnostic information may be provided to a user at certain time intervals. In an exemplary embodiment, diagnostic information may be provided to a user both at certain time intervals as well as when it is determined that the state of a pipeline is poor. Also, not only diagnostic information, but also actual measurement data on a database may be periodically provided to a user.

For example, actual measurement data obtained by monitoring the state of a fluid in a pipeline and information obtained by analyzing and diagnosing the state and surrounding environment of the pipeline may be provided to a user. Therefore, the user may check the fluid level and the flow rate of a fluid, particles and sludge in the fluid, and the concentration and the pressure of the fluid in real time. Also, based on the data regarding the state of the fluid, the user may directly diagnose the state and the surrounding environment inside the pipeline 1300. Also, statistical diagnostic indices such as, for example, an hourly average fluid level, a daily average fluid level, a daily maximum fluid level, and a daily fluid level change may be calculated and provided to the user. These statistical diagnostic indices may be used to identify and detect the state of a pipeline, and a problematic situation that may arise based on the state may be predicted in advance and provided to the user as information.

Thereafter, the pipeline is cleaned by using ultrasound waves based on diagnostic information (operation S140). Cleaning of a pipeline using ultrasound waves may be performed automatically based on the diagnostic information obtained in operation S130. Alternatively, the user may check diagnostic information and manually operate cleaning of the pipeline.

Still referring to FIG. 10, operation S140 may be replaced with operation S140a of FIG. 7. Thus, in FIG. 10, the pipeline may be cleaned by using both nano-micro bubbles and ultrasound waves.

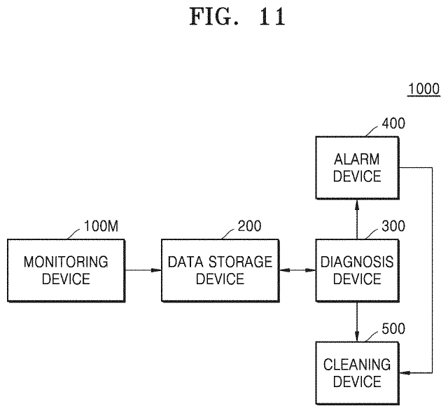

FIG. 11 is a schematic block diagram of a semiconductor equipment management system according to an exemplary embodiment. For convenience of explanation, a further description of elements and technical aspects previously described may be omitted.

Referring to FIG. 11, a semiconductor equipment management system 1000 according to an exemplary embodiment includes a monitoring device 100M, a data storage device 200, a diagnosis device 300, an alarm device 400, and a cleaning device 500.

The monitoring device 100M may monitor the state of a fluid in a pipeline (see 1300 of FIG. 2) by using various types of sensors. The monitoring device 100M may include the components described above according to exemplary embodiments to monitor the state of the fluid in the pipeline 1300. For example, the monitoring device 100M may measure the fluid level of the fluid in the pipeline 1300 by using an ultrasound wave sensor, a light sensor, a laser sensor, or a pulse sensor. In the semiconductor equipment management system 1000 according to an exemplary embodiment, the monitoring device 100M may measure the fluid level of the fluid in the pipeline 1300 by using a light sensor (see 100 in FIG. 2). As described above, the light sensor 100 may be safe from a risk due to overflow of the fluid by measuring the fluid level through an observation window (see 1100 of FIG. 2) without punching a hole through the observation window. Also, the monitoring device 100M may use an ultrasound wave sensor to measure the flow rate of the fluid flowing in the pipeline 1300 or to measure the number of particles in the fluid. Furthermore, the monitoring device 100M may measure fluid concentration or gas concentration by using an ultrasound wave concentration sensor or a gas sensor, and may measure the temperature of the fluid or the pressure in the pipeline by using a temperature sensor or a pressure sensor. The monitoring device 100M may also use an acoustic sensor to measure noise in the pipeline or use a vibration sensor to measure vibration in the pipeline.

The sensors used by the monitoring device 100M are not limited to the above-described sensors. For example, to more precisely and objectively measure the state of a fluid in the pipeline 1300, various sensors other than the sensors described above may be employed by the monitoring device 100M.

The data storage device 200 may store actual measurement data collected by the monitoring device 100M using various sensors, and may store a database constructed by using collected actual measurement data. The data storage device 200 may be implemented as a storage device of, for example, a computer. The data storage device include any device capable of storing data including, for example, a nonvolatile memory device.

The diagnosis device 300 may analyze and diagnose the state or surrounding environment of the pipeline 1300 by using actual measurement data stored in the data storage device 200 and a corresponding database. For example, the diagnosis device 300 may analyze and diagnose the state or surrounding environment of the pipeline 1300 based on actual measurement data and/or databases by using an analysis and diagnostic program. Also, the diagnosis device 300 may analyze and diagnose the state or surrounding environment of the pipeline 1300 based on deep learning using algorithms such as, for example, ANN, DNN, CNN, RNN, GAN, etc., by using actual measurement data and/or a database. The diagnosis device 300 may be implemented by, for example, a general personal computer (PC), a workstation, or a supercomputer capable of executing an analysis and diagnostic program or an algorithm for deep learning.

The diagnosis device 300 may be implemented using one or more hardware components, one or more software components, or a combination of one or more hardware components and one or more software components.

A hardware component may be, for example, a physical device that physically performs one or more operations, but is not limited thereto. Examples of hardware components include amplifiers, low-pass filters, high-pass filters, band-pass filters, analog-to-digital converters, digital-to-analog converters, and processing devices.

A software component may be implemented, for example, by a processing device controlled by software or instructions to perform one or more operations, but is not limited thereto. A computer, controller, or other control device may cause the processing device to run the software or execute the instructions.

A processing device may be implemented using one or more general-purpose or special-purpose computers, such as, for example, a processor, a controller and an arithmetic logic unit, a digital signal processor, a microcomputer, a field-programmable array, a programmable logic unit, a microprocessor, or any other device capable of running software or executing instructions. The processing device may run an operating system (OS), and may run one or more software applications that operate under the OS. The processing device may access, store, manipulate, process, and create data when running the software or executing the instructions. For simplicity, the singular term “processing device” may be used in the description, but one of ordinary skill in the art will appreciate that a processing device may include multiple processing elements and multiple types of processing elements. For example, a processing device may include one or more processors, or one or more processors and one or more controllers. In addition, different processing configurations are possible, such as parallel processors or multi-core processors.

The alarm device 400 may provide diagnostic information regarding the state or surrounding environment of the pipeline 1300 from the diagnosis device 300 to a user. For example, the alarm device 400 may provide diagnostic information regarding the state or surrounding environment of the pipeline 1300 in real time in the form of at least one of sound, light, an e-mail, a text message, and equipment interlock. Thus, the alarm device 400 may be, for example, a speaker that transmits a sound, a light source that emits a light, or a communication device that transmits an e-mail or a text message. Diagnostic information may be provided to the user only when it is determined that the state of a pipeline is poor, or may be provided to the user at a certain time interval and when it is determined that the state of a pipeline is poor.

The cleaning device 500 may clean the pipeline 1300 according to the diagnostic information from the diagnosis device 300. Also, the cleaning device 500 may clean the pipeline 1300 based on manipulation of a user who recognized the state of the pipeline 1300 through the alarm device 400. In the semiconductor equipment management system 1000 according to an exemplary embodiment, the cleaning device 500 may be the cleaning device 500 showed in FIG. 3A. Accordingly, the cleaning device 500 may include the flexible structure 501, the ultrasound wave generators 510, and the coupling mechanism 520. The cleaning device 500 may generate multi-frequency ultrasound waves by using the ultrasound wave generators 510 to clean the pipeline 1300. Also, the cleaning device 500 may improve the effect of cleaning the pipeline 1300 by adding nano-micro bubbles to a fluid and cleaning the pipeline 1300 by using the nano-micro bubbles and ultrasound waves. The nano-micro bubbles may be added directly to the fluid in the pipeline 1300 or may be added to corresponding semiconductor equipment during a semiconductor process.

As is traditional in the field of the inventive concept, exemplary embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, etc., which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions. Aspects of the inventive concept may be embodied as a system, method or computer program product.

While the inventive concept has been particularly shown and described with reference to the exemplary embodiments thereof, it will be understood by those of ordinary skill in the art that various changes in form and detail may be made therein without departing from the spirit and scope of the inventive concept as defined by the following claims.

1. A method of cleaning semiconductor equipment, the method comprising:
monitoring a state of a fluid in a pipeline of the semiconductor equipment;
constructing a database by using data collected through the monitoring;
diagnosing a state of the pipeline based on the data collected through the monitoring and stored in the database; and
cleaning the pipeline by using an ultrasound wave when the state of the pipeline is diagnosed as being abnormal,
wherein the pipeline is cleaned by using at least two ultrasound wave generators.

2. The method of claim 1, wherein the pipeline is cleaned by using multi-frequency ultrasound waves generated by the at least two ultrasound wave generators.

3. The method of claim 2, wherein the multi-frequency ultrasound waves are generated by diversifying ultrasound wave generation time points of the at least two ultrasound wave generators.

4. The method of claim 2, wherein the at least two ultrasound wave generators are at least three ultrasound wave generators, and ultrasound wave generation time points are diversified to two or more ultrasound wave generation time points.

5. The method of claim 1, wherein the at least two ultrasound wave generators are configured to be coupled to a flexible structure capable of surrounding an outer wall of the pipeline regardless of a size of the pipeline and to contact the outer wall and surround a lower portion of the outer wall.

6. The method of claim 1, wherein the fluid comprises microbubbles or nanobubbles.

7. The method of claim 6, wherein the microbubbles or nanobubbles are added to the fluid in the pipeline from at least one piece of equipment performing a semiconductor process.

8. The method of claim 1, wherein monitoring the state of the fluid comprises measuring at least one of a fluid level of the fluid, a flow rate of the fluid, a concentration of the fluid, a temperature of the fluid, a pressure of the fluid, an amount of particles of sludge in the fluid, noise in the pipeline, vibration in the pipeline, and pressure in the pipeline.

9. The method of claim 1, wherein monitoring the state of the fluid comprises measuring a fluid level of the fluid in the pipeline,
wherein the fluid level of the fluid is measured using a light sensor attached to an observation window of the pipeline,
wherein the light sensor is attached to the observation window without punching a hole through the observation window.

10. The method of claim 1, wherein monitoring the state of the fluid comprises measuring noise or vibration in the pipeline by using an acoustic sensor or a vibration sensor.

11. The method of claim 1, wherein diagnosing the state of the pipeline is performed based on deep learning using the data stored in the database.

12. The method of claim 1, further comprising:
after diagnosing the state of the pipeline, providing diagnostic information to a user in real time through at least one of sound, light, an e-mail, a text message, and interlock of equipment.

13. A method of cleaning semiconductor equipment, the method comprising:
monitoring a state of a fluid in a pipeline of the semiconductor equipment;
constructing a database by using data collected through the monitoring;
diagnosing a state of the pipeline based on the data collected through the monitoring and stored in the database; and
cleaning the pipeline by using bubbles and an ultrasound wave when the state of the pipeline is diagnosed as being abnormal,
wherein the bubbles are microbubbles or nanobubbles.

14. The method of claim 13, wherein the ultrasound wave is generated by using at least two ultrasound wave generators, and the at least two ultrasound wave generators are configured to be coupled to a flexible structure capable of surrounding an outer wall of the pipeline regardless of a size of the pipeline and to contact the outer wall and surround a lower portion of the outer wall,
wherein the pipeline is cleaned by using multi-frequency ultrasound waves generated by the at least two ultrasound wave generators.

15. The method of claim 13, further comprising:
adjusting a frequency of the ultrasound wave by using temperature information provided by a user or temperature information measured by a temperature sensor.

16. The method of claim 13, wherein the bubbles are added to the fluid in the pipeline from at least one of equipment performing a semiconductor process.

17. The method of claim 13, wherein monitoring the state of the fluid comprises measuring at least one of a fluid level of the fluid, a flow rate of the fluid, a concentration of the fluid, a temperature of the fluid, a pressure of the fluid, an amount of particles of sludge in the fluid, noise in the pipeline, vibration in the pipeline, and pressure in the pipeline.

18. The method of claim 13, wherein diagnosing the state of the pipeline is performed based on deep learning using the data stored in the database.

19. The method of claim 13, further comprising:
after diagnosing the state of the pipeline, providing diagnostic information to a user in real time through at least one of sound, light, an e-mail, a text message, and interlock of equipment.

20-25. (canceled)

26. A method of cleaning semiconductor equipment, the method comprising:
monitoring a state of a fluid in a pipeline of the semiconductor equipment;
constructing a database by using data collected through the monitoring;
diagnosing a state of the pipeline based on the data collected through the monitoring and stored in the database;
providing diagnostic information to a user in real time through at least one of sound, light, an e-mail, a text message, and interlock of equipment; and
cleaning the pipeline by using bubbles and an ultrasound wave when the state of the pipeline is diagnosed as being abnormal,
wherein the ultrasound wave is generated by using at least two ultrasound wave generators, and the bubbles are microbubbles or nanobubbles.
